(19) United States
(12) Patent Application Publication
(10) Pub. No.: US 2011/0181298 A1
(43) Pub. Date: Jul. 28, 2011

(54) MEASUREMENT APPARATUS AND TEST APPARATUS

(75) Inventors: Yasuhide KURAMOCHI, Gunma (JP); Masayuki KAWABATA, Saitama (JP)

(73) Assignee: ADVANTEST CORPORATION, Tokyo (JP)

(21) Appl. No.: 12/905,033

(22) Filed: Oct. 14, 2010

(30) Foreign Application Priority Data
Oct. 29, 2009 (JP) 2009-249401

(51) Int. Cl. G01R 29/26

(52) U.S. Cl. 324/613

(57) ABSTRACT

Provided is a measurement apparatus that measures a signal under measurement input thereto, comprising a plurality of signal measurement circuits that measure a level of a signal input thereto, according to a sampling clock provided thereto; a noise measuring section that measures a noise component propagated from a first signal measurement circuit to a second signal measurement circuit, among the plurality of signal measurement circuits, based on a measurement result output by the second signal measurement circuit; and a clock supplying section that, when the signal under measurement is being measured, supplies the first signal measurement circuit and the second signal measurement circuit with sampling clocks having the same period and that, when the noise component is being measured, supplies the first signal measurement circuit and the second signal measurement circuit with sampling clocks having different periods.

### BACKGROUND

1. Technical Field

The present invention relates to a measurement apparatus and a test apparatus.

2. Related Art

A conventional apparatus is known in which a plurality of measurement circuits for measuring signals are arranged in parallel, as shown in Patent Document 1, for example. Each measurement circuit is provided with a sampling clock that designates the timing at which the signal is measured. Each measurement circuit converts the signal level of the input signal into a digital value at the edge timing of the sampling clock. Patent Document 1: Japanese Patent Application Publication No. 2008-160545

When a plurality of measurement circuits are arranged in parallel as described above, each measurement circuit receives noise components caused by other measurement circuits. Since each measurement circuit operates in synchronization with a sampling clock, each measurement apparatus sends a noise component synchronized with the sampling clock to the other measurement circuits.

For example, the noise component is propagated via the substrates between the measurement circuits. If a shared signal is input to the measurement circuits, the noise component is propagated thought a shared signal line. If the measurement circuits receive power from a shared power supply, the noise component is propagated via the power supply. In an interleaved AD conversion apparatus, a plurality of AD converters are arranged near each other, a common signal is input to each AD converter, and power is supplied to each AD converter from a shared power supply, and therefore the problem with the noise component is especially pronounced.

Conventionally, a dedicated measurement circuit capable of operating at high speed is provide to measure the noise component caused by each measurement circuit. However, including a dedicated measurement circuit that is not used during actual operation decreases efficiency. Furthermore, it is impossible to measure the actual effect of the noise on each measurement circuit performing actual operation.

### SUMMARY

Therefore, it is an object of an aspect of the innovations herein to provide a measurement apparatus and a test apparatus, which are capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a measurement apparatus that measures a signal under measurement input thereto, comprising a plurality of signal measurement circuits that measure a level of a signal input thereto, according to a sampling clock provided thereto; a noise measuring section that measures a noise component propagated from a first signal measurement circuit to a second signal measurement circuit, among the plurality of signal measurement circuits, based on a measurement result output by the second signal measurement circuit; and a clock supplying section that, when the signal under measurement is being measured, supplies the first signal measurement circuit and the second signal measurement circuit with sampling clocks having the same period and that, when the noise component is being measured, supplies the first signal measurement circuit and the second signal measurement circuit with sampling clocks having different periods.

According to a second aspect related to the innovations herein, provided is a test apparatus that uses the measurement apparatus of the first aspect.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows an exemplary configuration of a measurement apparatus 100 according to an embodiment of the present invention.

FIG. 2 is a timing chart showing an exemplary operation of the measurement apparatus 100 in the noise measurement mode.

FIG. 3 shows another exemplary configuration of the measurement apparatus 100.

FIG. 4 is a timing chart showing an exemplary operation of the measurement apparatus 100 of FIG. 3 in the signal measurement mode.

FIG. 5 shows another exemplary signal measurement circuit 10.

FIG. 6 shows another exemplary operation of the measurement apparatus 100 in the noise measurement mode.

FIG. 7 shows an exemplary configuration of a test apparatus 200 along with a device under test 300.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

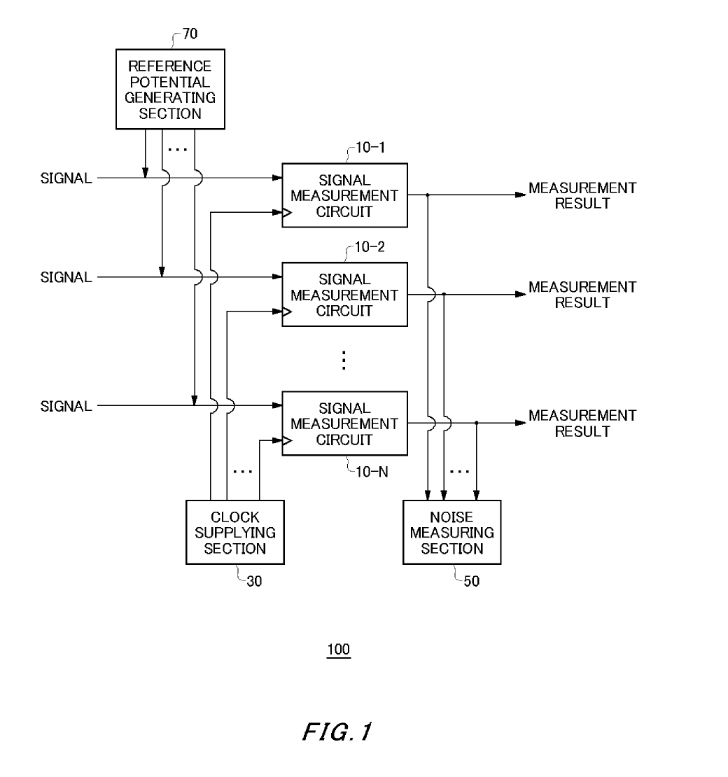

FIG. 1 shows an exemplary configuration of a measurement apparatus 100 according to an embodiment of the present invention. The measurement apparatus 100 measures a signal under measurement input thereto, and includes a plurality of signal measurement circuits 10, a clock supplying section 30, a noise measuring section 50, and a reference potential generating section 70. The signal measurement circuits 10 may be formed in the same chip. The clock supplying section 30, the noise measuring section 50, and the reference potential generating section 70 may also be formed in the same chip. The signal measurement circuits 10 may receive power from a shared power supply or power line.

Each signal measurement circuit 10 measures the level of a signal input thereto according to a sampling clock provided thereto. Each signal measurement circuit 10 may be an AD converter that detects the signal level of the input signal at the timing of a rising edge or a falling edge of the sampling clock and outputs a measurement result by converting this signal level into a digital value. Each signal measurement circuit 10 may receive a different signal under measurement, or the signal measurement circuits 10 may all receive the same signal under measurement.

The clock supplying section 30 supplies the sampling clock to the signal measurement circuits 10. When measuring the signal under measurement, the clock supplying section 30 supplies the signal measurement circuits 10 with a sampling clock having a predetermined period.

The noise measuring section 50 measures the noise component propagated between the signal measurement circuits 10. The noise component may be a noise component caused by the measurement operation of the signal measurement circuits 10. Since each signal measurement circuit 10 operates according to the sampling clock with the predetermined period, the noise component has a period corresponding to the sampling clock.

The noise measuring section 50 measures the noise component over an interval during which the measurement apparatus 100 is not measuring a signal under measurement from the outside. The measurement apparatus 100 may have two operational modes that include a signal measurement mode for measuring a signal under measurement from the outside and a noise measurement mode for measuring a noise component propagated between the signal measurement circuits 10.

In the noise measurement mode, the noise measuring section 50 of the present embodiment measures the noise component that is propagated from a first signal measurement circuit 10 to a second signal measurement circuit 10 among the plurality of signal measurement circuits 10. The noise measuring section 50 measures the noise component based on the measurement result output by the second signal measurement circuit 10.

In the noise measurement mode, a prescribed potential is preferably input instead of the signal under measurement to the signal input terminal of the second signal measurement circuit 10, such that the measurement result does not include components other than the noise component. Furthermore, the prescribed potential is preferably input instead of the signal under measurement to the signal input terminal of the first signal measurement circuit 10, such that the first signal measurement circuit 10 does not generate a noise component that depends on the pattern of the input signal.

In this way, the measurement apparatus 100 can accurately measure the noise component caused by the measurement operation of the first signal measurement circuit 10. In the present embodiment, the reference potential generating section 70 inputs the prescribed potential to the first and second signal measurement circuits 10.

When in the noise measurement mode, the clock supplying section 30 inputs sampling clocks with different periods to the clock input terminals of the first and second signal measurement circuits 10. The clock supplying section 30 may input to the first signal measurement circuit 10 a first sampling clock whose period is the same as that of the sampling clock in the signal measurement mode, and may input to the second signal measurement circuit 10 a second sampling clock whose period differs from that of the first sampling clock.

The clock supplying section 30 may set the period difference between the sampling clocks supplied to the first and second signal measurement circuits 10 to be sufficiently less than the period of the first sampling clock supplied to the first signal measurement circuit 10. The clock supplying section 30 may set the period of the second sampling clock supplied to the second signal measurement circuit 10 to be Ts+ΔT. Here, Ts indicates the period of the sampling clock in the signal measurement mode.

Furthermore, the period of the second sampling clock is preferably set such that ΔT is not an integer multiple of Ts. If ΔT is an integer multiple of Ts, the sampling timing of the noise component becomes the same in each cycle of the noise component, and therefore the noise component cannot be sampled at uniform time intervals. Therefore, ΔT may be sufficiently less than Ts or greater than Ts.

For example, the clock supplying section 30 may set the period of the second sampling clock such that ΔT=k×Ts+dt, where k is an integer greater than 0 and dt is less than Ts. In other words, the second sampling clock may be set such that the period difference ΔT is not an integer multiple of the first sampling clock period Ts. Furthermore, ΔT may be less than the minimum operational period for which each signal measurement circuit 10 can operate.

With the above configuration, the measurement apparatus 100 can supply the second signal measurement circuit 10 with the second sampling clock having a period obtained by adding a very small period to the period of the noise component propagated by the second signal measurement circuit 10. Therefore, the second signal measurement circuit 10 operates to under-sample the noise component. In other words, the second signal measurement circuit 10 samples the noise component at uniform intervals with a time resolution corresponding to the period difference. Therefore, the second signal measurement circuit 10 can sample the noise component with a high frequency.

The noise measuring section 50 measures the noise component based on the measurement result output by the second signal measurement circuit 10. The noise measuring section 50 may judge whether the magnitude of the noise component is within a prescribed range. If the magnitude of the noise component is not within this prescribed range, the noise measuring section 50 may notify a user that there is insufficient isolation of the signal measurement circuits 10.

The noise measuring section 50 may judge whether a peak value, RMS value, average value, or the like of the level of the noise component measured by on the time axis is greater than a prescribed value. As another example, the noise measuring section 50 may judge whether a f=1/Ts component or a high-frequency component thereof, in a spectrum obtained by performing a Fourier transform on the measurement result output by the second signal measurement circuit 10, is greater than a prescribed value.

The first signal measurement circuit 10 and the second signal measurement circuit 10 do not refer to specific signal measurement circuits 10. The measurement apparatus 100 may measure the noise component among a plurality of signal measurement circuits 10 by sequentially changing the pair of signal measurement circuits 10 serving as the first signal measurement circuit 10 and the second signal measurement circuit 10.

The noise measuring section 50 may select the signal measurement circuit 10-1 as the first signal measurement circuit 10 and select another signal measurement circuit from 10-2 to 10-N sequentially as the second signal measurement circuit 10. As a result, the measurement apparatus 100 can measure the noise component propagated from the signal measurement circuit 10-1 to each of the other signal measurement circuits 10.

Similarly, the noise measuring section 50 may sequentially select each of the signal measurement circuits 10 to serve as the first signal measurement circuit 10. In other words, the noise measuring section 50 may measure the noise component for each combination of two signal measurement circuits 10. Instead, the noise measuring section 50 may measure the noise components for predetermined combinations of signal measurement circuits 10 only.

When in the noise measurement mode, the clock supplying section 30 preferably does not supply a sampling clock to signal measurement circuits 10 other than the first signal measurement circuit 10-1 and the second signal measurement circuit 10-2. As a result, the effect of noise components propagated from other signal measurement circuits 10 can be eliminated.

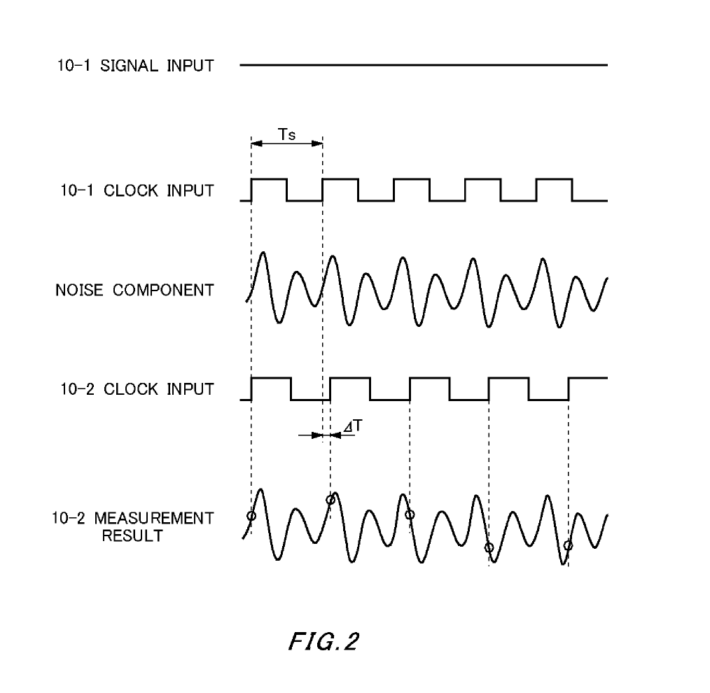

FIG. 2 is a timing chart showing an exemplary operation of the measurement apparatus 100 in the noise measurement mode. In FIG. 2, the horizontal axis represents time and the vertical axis represents signal level. The following description uses the signal measurement circuit 10-1 as the first signal measurement circuit 10 and the signal measurement circuit 10-2 as the second signal measurement circuit 10.

In the noise measurement mode, a prescribed reference potential is provided to the signal input terminal of each signal measurement circuit 10. A sampling clock with a period Ts that is the same as the period during the signal measurement mode is supplied to the first signal measurement circuit 10-1. Therefore, a noise component with a period corresponding to the sampling clock Ts is generated by the first signal measurement circuit 10-1. This noise component is propagated to the second signal measurement circuit 10-2 via a circuit substrate, signal line, power supply line, or the like.

The second signal measurement circuit 10-2 is supplied with a sampling clock having a period of Ts+ΔT. The sampling clock for the second signal measurement circuit 10-2 has a period that is ΔT greater than the period Ts of the propagated periodic noise component. Therefore, for each cycle of the noise component, the relative phase of the sampling clock with respect to the noise component shifts by ΔT. Accordingly, the second signal measurement circuit 10-2 samples the noise component uniformly with a time resolution of ΔT. Therefore, the noise measuring section 50 can measure the magnitude of the noise component from the measurement result output by the second signal measurement circuit 10-2.

The measurement apparatus 100 described above can measure the noise components based on the measurement results of the measurement circuits, and therefore need not include a dedicated measurement circuit. Furthermore, the measurement apparatus 100 can measure the noise component propagated through a measurement circuit used to measure a signal under measurement.

Furthermore, by sampling at uniform intervals, the measurement apparatus 100 can measure a noise component with a higher frequency than the operational frequency of the signal measurement circuits 10. By changing the frequency difference between the sampling clocks, the measurement apparatus 100 can set a time resolution for the noise component measurement. Furthermore, the measurement apparatus 100 can easily measure the noise component for each combination of a signal measurement circuit 10 serving as the noise generation source and a signal measurement circuit serving as the noise propagation destination.

As a result of the above operation, the first signal measurement circuit 10-1 also outputs a measurement result corresponding to the sampling clock with a period Ts. The noise measuring section 50 may receive the measurement result output by the first signal measurement circuit 10-1 in parallel with the measurement result output by the second signal measurement circuit 10-2. The noise measuring section 50 may also measure a second noise component propagated from the second signal measurement circuit 10-2 to the first signal measurement circuit 10-1, based on these measurement results.

However, it should be noted that the second signal measurement circuit 10-2 operates at a different frequency than during the signal measurement mode. Therefore, the second noise component has a different period than the component propagated during the signal measurement mode. Accordingly, in order to estimate the noise component propagated during the signal measurement mode, it is preferable to sequentially perform two measurements in which each of the pair of signal measurement circuits 10 serves once as the first signal measurement circuit 10 and once as the second signal measurement circuit 10.

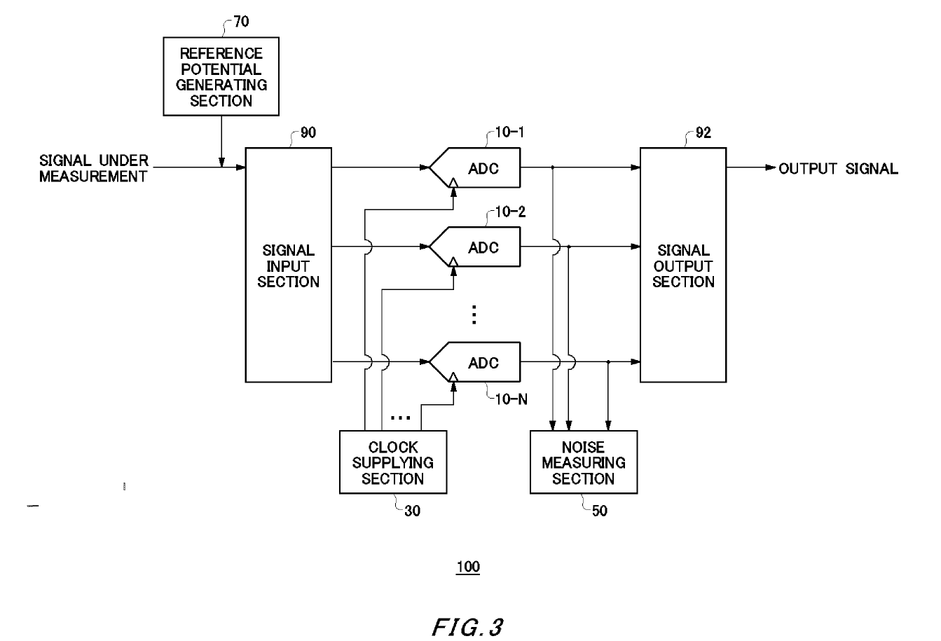

FIG. 3 shows another exemplary configuration of the measurement apparatus 100. The measurement apparatus 100 of the present embodiment further includes a signal input section 90 and a signal output section 92 in addition to the configuration of the measurement apparatus 100 described in relation to FIGS. 1 and 2. The remaining configuration of this measurement apparatus 100 may be the same as that of the measurement apparatus 100 described in FIG. 1 or 2.

The measurement apparatus 100 of the present embodiment includes AD converters as the signal measurement circuits 10. In the noise measurement mode, the operation of the signal measurement circuits 10, the clock supplying section 30, and the noise measuring section 50 may be the same as in the measurement apparatus 100 described in relation to FIGS. 1 and 2.

The signal input section 90 inputs the same signal under measurement to each of the signal measurement circuits 10. The signal input section 90 branches a signal under measurement supplied from the outside to input the signal under measurement to the signal input terminal of each signal measurement circuit 10. The signal input section 90 preferably inputs the signal under measurement to each signal measurement circuit 10 via branched paths that each have substantially the same delay amount.

In order to decrease the delay difference between the branched paths, the signal measurement circuits 10 are arranged near each other. The signal input section 90, the signal measurement circuits 10, and the signal output section 92 may be formed in the same semiconductor chip. The clock supplying section 30, the noise measuring section 50, and the reference potential generating section 70 may also be formed in the same semiconductor chip. The reference potential generating section 70 may input a prescribed reference potential into the signal input section 90 instead of the signal under measurement.

In the signal measurement mode, the clock supplying section 30 causes the phases of the sampling clock provided to each signal measurement circuit 10 to be different. The period of each sampling clock is the same. The clock supplying section 30 may sequentially shift the phases of the sampling clocks provided to a signal measurement circuit 10 by Ts/N per sampling clock. Here, Ts indicates the period of the sampling clock and N indicates the number of signal measurement circuits 10. As a result, the signal measurement circuits 10 sequentially sample the signal under measurement with a time resolution of Ts/N.

The signal output section 92 combines the measurement results output by the signal measurement circuits 10, and outputs the combined result. The combining may involve arranging the digital values output by the signal measurement circuits 10 in the order in which the values were sampled. With this configuration, the measurement apparatus 100 can measure a high-frequency signal under measurement using an AD converter that operates at relatively low speed.

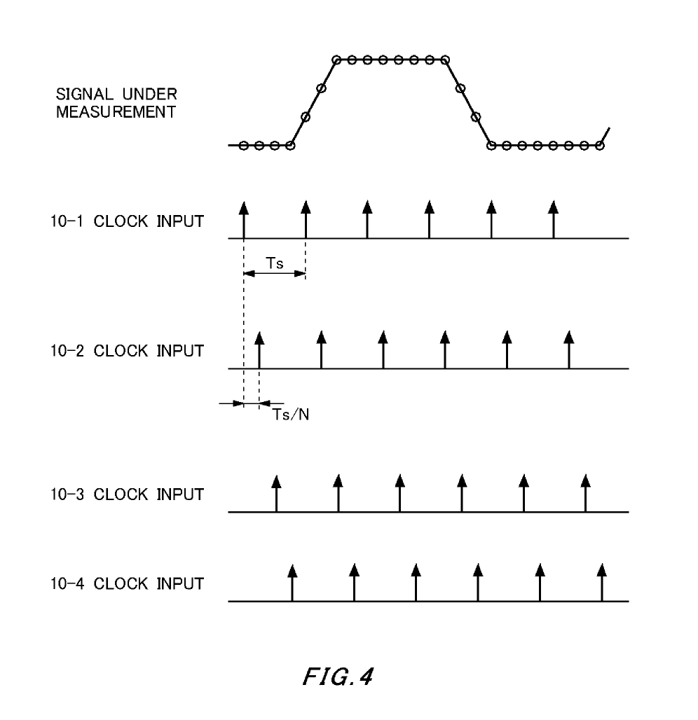

FIG. 4 is a timing chart showing an exemplary operation of the measurement apparatus 100 of FIG. 3 in the signal measurement mode. In FIG. 4, the horizontal axis represents time and the vertical axis represents signal level. The measurement apparatus 100 of the present embodiment includes four signal measurement circuits 10.

The signal input section 90 inputs the same signal under measurement to the signal input terminal of each signal measurement circuit 10. The clock supplying section 30 inputs, to the clock input terminals of the signal measurement circuit 10, a sampling clock having the same period and whose phase is sequentially shifted by Ts/4. Therefore, the signal measurement circuits 10 can operate together to measure the signal under measurement with a time resolution of Ts/4.

The signal output section 92 creates a single data sequence in which the data values of the measurement results output by the signal measurement circuits 10 are arranged in the sampling order. As a result, the measurement apparatus 100 can obtain measurement results by sampling the signal under measurement with a time resolution of Ts/4, as shown in FIG. 4.

In the measurement apparatus 100, the signal measurement circuits 10 are arranged near each other and each receive the same branched signal under measurement. Each signal measurement circuit 10 receives supply power from the same power supply line. Therefore, the noise component propagated between the signal measurement circuits 10 becomes more prominent. Furthermore, a high-frequency noise component corresponding to the AD conversion operation is generated by each signal measurement circuit 10. The noise component measurement described in relation to FIGS. 1 and 2 can be used to accurately measure a high-frequency noise component, and can therefore be used effectively by the measurement apparatus 100.

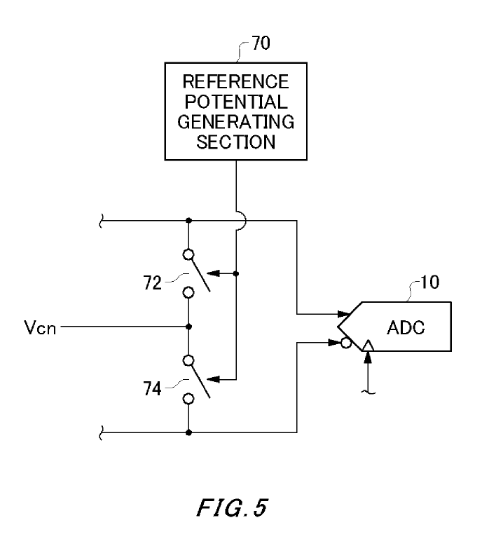

FIG. 5 shows another exemplary signal measurement circuit 10. The signal measurement circuit 10 of the present embodiment includes a differential AD converter that converts the level of a differential input signal, which has a predetermined common potential Vcm as a reference, into a digital value according to the sampling clock. The common potential Vcm may define the intermediate potential of the differential input signal. The signal measurement circuit 10 may include a common input terminal into which the common potential Vcm is input.

The reference potential generating section 70 may input the common potential Vcm into the first and second signal measurement circuits 10 as the reference potential described above. More specifically, the reference potential generating section 70 may input the common potential Vcm into both the positive and negative differential input terminals of the signal measurement circuit 10.

The measurement apparatus 100 may include a switch 72 and a switch 74 corresponding to each signal measurement circuit 10. The switch 72 switches whether the common potential Vcm is applied to the positive input terminal of the signal measurement circuit 10. The switch 74 switches whether the common potential Vcm is input to the negative input terminal of the signal measurement circuit 10.

More specifically, one end of the switch 72 and one end of the switch 74 are respectively connected to the positive input terminal and the negative input terminal of the signal measurement circuit 10. The other ends of the switch 72 and the switch 74 are connected to each other, and the common potential Vcm is applied to these other ends. The reference potential generating section 70 turns OFF the switch 72 and the switch 74 in the signal measurement mode, and turns ON the switch 72 and the switch 74 in the noise measurement mode.

With this configuration, a constant reference potential can be easily input to each signal measurement circuit 10 in the noise measurement mode. Furthermore, by inputting the common potential to the second signal measurement circuit 10, the measurement range of the positive voltage and negative voltage can be ensured.

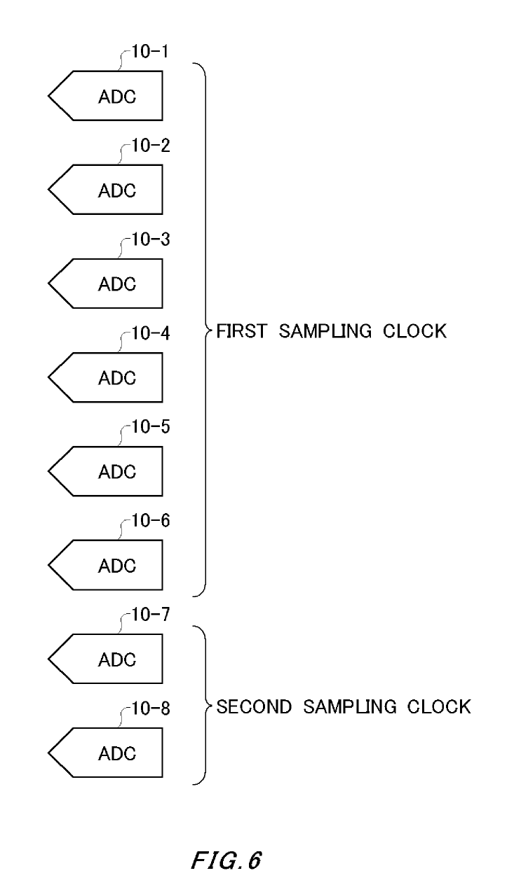

FIG. 6 shows another exemplary operation of the measurement apparatus 100 in the noise measurement mode. The measurement apparatus 100 described in relation to FIGS. 1 to 5 selects a single first signal measurement circuit 10 and a single second signal measurement circuit 10. The measurement apparatus 100 of the present embodiment, however, measures the noise component using a plurality of signal measurement circuits 10 for at least one of the first and second signal measurement circuits 10. FIG. 6 shows an exemplary measurement apparatus 100 that includes eight signal measurement circuits 10.

The measurement apparatus 100 may set M signal measurement circuits 10 as the first signal measurement circuits 10, where M is an integer greater than 1. In the example of FIG. 6, M=6. The clock supplying section 30 supplies the M first signal measurement circuits 10 with the first sampling clock having the period Ts.

The measurement apparatus 100 may set L signal measurement circuits 10 as the second signal measurement circuits 10, where L is an integer greater than 1 and is such that, in the present example, L+M is no greater than 8. In the example of FIG. 6, M=2. The clock supplying section 30 supplies the L second signal measurement circuits 10 with the second sampling clock having a period Ts+ΔT.

The measurement apparatus 100 may set M signal measurement circuits 10 arranged continuously as the first signal measurement circuits 10. The continuous M signal measurement circuits 10 refer to a prescribed signal measurement circuit 10-1 and the M-1 signal measurement circuits 10 selected in order of the signal measurement circuits 10 having the smallest distance from the signal measurement circuit 10-1.

The measurement apparatus 100 may set L signal measurement circuits 10 arranged in continuously as the second signal measurement circuits 10. The measurement apparatus 100 selects the first signal measurement circuits 10 and the second signal measurement circuits 10 such that they do not overlap with each other.

The noise measuring section 50 may measure the average of the noise components of the L second signal measurement circuits 10. The noise measuring section 50 may perform this measurement while associating the average value of the distance between the first signal measurement circuits 10 and the second signal measurement circuits 10 with the average value of the noise component. The noise measuring section 50 may change the combination of first signal measurement circuits 10 and second signal measurement circuits 10 such that the average distance between the first signal measurement circuits 10 and the second signal measurement circuits 10 changes, and measure the magnitude of the noise component for each average distance between signal measurement circuits 10.

If the characteristics of the signal measurement circuits 10 are the same, the magnitude of the measured noise component depends on the distance between the first signal measurement circuits 10 and the second signal measurement circuits 10. Therefore, using the method described in relation to FIGS. 1 and 2, among all combinations of first signal measurement circuits 10 and second signal measurement circuits 10, redundant measurement can be prevented for combinations having the same distance between the circuits.

With the method described in relation to FIGS. 1 and 2, however, the first and second signal measurement circuits 10 are selected one at a time, and therefore variation of the signal measurement circuits 10 affects the noise component measurement results. In the method of the present embodiment, a plurality of signal measurement circuits 10 are used, and therefore the variation is decreased.

FIG. 6 shows an example in which either the first sampling clock or the second sampling clock is supplied to each of the signal measurement circuits 10, but a sampling clock need not be provided to every signal measurement circuit 10. The measurement apparatus 100 may cause each signal measurement circuit 10 to function as a first signal measurement circuit 10, a second signal measurement circuit 10, or a signal measurement circuit 10 that does not receive a clock.

When a plurality of signal measurement circuits 10 function as second signal measurement circuits 10, each second signal measurement circuit 10 propagates, in addition to the noise component from the first signal measurement circuits 10, a noise component from other second signal measurement circuits 10. The noise measuring section 50 may eliminate the f=1/(Ts+ΔT) component from the measurement results of the second signal measurement circuits 10 or extract the f=1/Ts component, and measure the magnitude of the noise component based thereon.

The measurement apparatus 100 may measure the noise component by setting a plurality of first signal measurement circuits 10 and a single second signal measurement circuit 10. The measurement apparatus 100 may select a single second signal measurement circuit 10 and cause all of the other signal measurement circuits 10 to operate as first signal measurement circuits 10. In this case, the sum of the noise components propagated to a first signal measurement circuit 10 from all other signal measurement circuits 10 can be measured by a single measurement.

The measurement apparatus 100 may set a plurality of signal measurement circuits 10 at substantially equal distances from a second signal measurement circuit 10 to be the first signal measurement circuits 10. The measurement apparatus 100 may set a signal measurement circuit 10 arranged substantially in the center to be the second signal measurement circuit 10, and set two signal measurement circuits 10 arranged at equal distances on both sides of the second signal measurement circuit 10 to be the first signal measurement circuits 10.

The measurement apparatus 100 may measure the noise component for each of a plurality of groups of first signal measurement circuits 10 at different distances from the second signal measurement circuit 10. The clock supplying section 30 supplies each of these first signal measurement circuits 10 with the sampling clock having the period Ts, and supplies the second signal measurement circuit 10 with the sampling clock having the period Ts+ΔT.

The combinations of first signal measurement circuits 10 and second signal measurement circuits 10 are not limited to the examples described above. The measurement apparatus 100 may measure the noise component for a wide variety of combinations of first signal measurement circuits 10 and second signal measurement circuits 10.

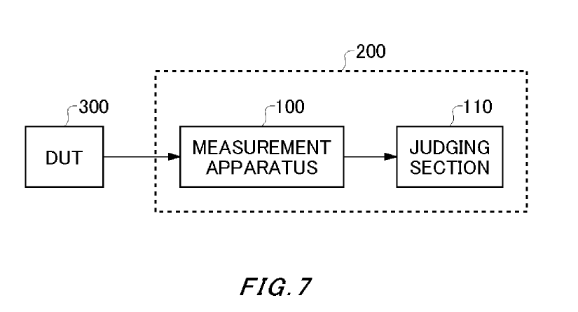

FIG. 7 shows an exemplary configuration of a test apparatus 200 along with a device under test 300. The test apparatus 200 tests the device under test 300, which may be a semiconductor circuit, and includes the measurement apparatus 100 and a judging section 110.

The measurement apparatus 100 may have the function and configuration of any of the measurement apparatuses 100 described in relation to FIGS. 1 to 6. The measurement apparatus 100 measures a signal under measurement output by the device under test 300.

The judging section 110 judges acceptability of the device under test 300 based on the measurement results of the signal under measurement from the measurement apparatus 100. The judging section 110 may judge the acceptability of the device under test 300 based on a logic pattern or waveform characteristics such as the jitter amount of the signal under measurement measured by the measurement apparatus 100, for example.

The test apparatus 200 may further include a signal generating section that generates a test signal causing the device under test 300 to operate, a power supply section that supplies power to the device under test 300, or the like. The measurement apparatus 100 may be a BIST circuit provided in the same chip as the device under test 300.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A measurement apparatus that measures a signal under measurement input thereto, comprising:
a plurality of signal measurement circuits that measure a level of a signal input thereto, according to a sampling clock provided thereto;
a noise measuring section that measures a noise component propagated from a first signal measurement circuit to a second signal measurement circuit, among the plurality of signal measurement circuits, based on a measurement result output by the second signal measurement circuit; and
a clock supplying section that, when the signal under measurement is being measured, supplies the first signal measurement circuit and the second signal measurement circuit with sampling clocks having the same period and that, when the noise component is being measured, supplies the first signal measurement circuit and the second signal measurement circuit with sampling clocks having different periods.

2. The measurement apparatus according to claim 1, wherein
when the noise component is being measured, the clock supplying section supplies the first signal measurement circuit with a sampling clock having the same period as the sampling clock supplied when measuring the signal under measurement and supplies the second signal measurement circuit with a sampling clock having a different period than the sampling clock supplied when measuring the signal under measurement.

3. The measurement apparatus according to claim 2, further comprising a reference potential generating section that, when the noise component is being measured, inputs a predetermined reference potential to the second signal measurement circuit.

4. The measurement apparatus according to claim 3, wherein
the reference potential generating section inputs the reference potential to the first signal measurement circuit.

5. The measurement apparatus according to claim 4, wherein
each signal measurement circuit converts a level of a differential input signal, which has a predetermined common potential as a reference, into a digital value, according to the sampling clock, and
the reference potential generating section inputs the common potential to the first signal measurement circuit and the second signal measurement circuit as the reference potential.

6. The measurement apparatus according to claim 1, wherein
when the signal under measurement is being measured, the clock supplying section changes a phase of each of the sampling clocks supplied to the signal measurement circuits, and
the measurement apparatus further comprises:
a signal input section that, when the signal under measurement is being measured, inputs the same signal under measurement to each signal measurement circuit; and
a signal output section that, when the signal under measurement is being measured, combines the measurement results output by the signal measurement circuits and outputs the combined result.

7. The measurement apparatus according to claim 1, wherein
the measurement apparatus sequentially changes a combination of the first signal measurement circuit and the second signal measurement circuit among the plurality of signal measurement circuits, and measures the noise component for each combination.

8. The measurement apparatus according to claim 1, wherein
the noise measuring section further measures a noise component propagated from the second signal measurement circuit to the first signal measurement circuit, based on the measurement result output by the first signal measurement circuit.

9. The measurement apparatus according to claim 1, wherein
the clock supplying section sets M of the plurality of signal measurement circuits to be a plurality of the first signal measurement circuits, where M is an integer greater than 1, and supplies the first signal measurement circuits with sampling clocks having the same period.

10. The measurement apparatus according to claim 9, wherein
the clock supplying section sets a plurality of signal measurement circuits that are at substantially the same distance from the second signal measurement circuit to be the first signal measurement circuits, and supplies the first signal measurement circuits with sampling clocks having the same period.

11. The measurement apparatus according to claim 1, wherein
the clock supplying section sets M signal measurement circuits arranged continuously among the plurality of signal measurement circuits to be a plurality of the first signal measurement circuits, where M is an integer greater than 1, supplies the first signal measurement circuits with sampling clocks having a first period, sets L signal measurement circuits arranged continuously among the plurality of signal measurement circuits to be a plurality of the second signal measurement circuits, where L is an integer greater than 1, and supplies the second signal measurement circuits with sampling clocks having a second period, and
the noise measuring section measures an average of the noise components of the second signal measurement circuits.

12. The measurement apparatus according to claim 1, wherein
when the noise component is being measured, the clock supplying section sets the period of the sampling clock supplied to the first signal measurement circuit such that a period difference between the sampling clocks supplied to the first signal measurement circuit and the second signal measurement circuit is not an integer multiple of the period of the sampling clock supplied to the first signal measurement circuit.

13. A test apparatus that tests a device under test, comprising:
the measurement apparatus according to claim 1 that measures a signal under measurement output by the device under test; and
a judging section that judges acceptability of the device under test based on the measurement result of the measurement apparatus.
